(19) United States
(12) Patent Application Publication
(10) Pub. No.: US 2011/0147936 A1
(43) Pub. Date: Jun. 23, 2011

(54) SEMICONDUCTOR DEVICE AND DAMASCENE STRUCTURE

(75) Inventors: Jinn P. Chu, Taipei (TW); Tung-Yuan Yu, Taipei (TW); Chon-Hsin Lin, Taipei (TW)

(73) Assignee: National Taiwan Unversity of Science & Technology, Taipei (TW)

(21) Appl. No.: 12/776,414

(22) Filed: May 9, 2010

(30) Foreign Application Priority Data
Dec. 21, 2009 (TW) 098143859

(51) Int. Cl. H01L 23/532

(52) U.S. Cl. 257/751; 257/E23.161

(57) ABSTRACT

The present invention provides a semiconductor device, including a silicon-containing material, a conductive layer deposited on the silicon-containing material, and a diffusion barrier layer interposed between the silicon-containing material and the conductive layer, wherein the diffusion barrier layer contains a rare earth scandate. The present invention further provides a damascene structure containing the rare earth scandate as diffusion barrier.

This application claims priority of Taiwan Patent Application No. 098143859, filed on Dec. 21, 2009, the entirety of which is incorporated by reference herein.

### BACKGROUND OF THE INVENTION

1. Field of the Invention

The present invention relates to a semiconductor device, and in particular relates to a semiconductor device containing a diffusion barrier layer formed of a rare earth scandate.

2. Description of the Related Art

The semiconductor integrated circuit industry has been experiencing rapid growth. Technological advances in IC materials and design have produced subsequent generations of ICs where each IC is smaller and more complex than circuits of the previous generation. These advances have increased the complexity of processing and manufacturing ICs and, for these advances to be realized, similar developments in IC processing and manufacturing are needed. In the course of IC evolution, functional density (i.e., the number of interconnected devices per chip area) has generally increased while geometry size (i.e., the smallest component or line that can be created using a fabrication process) has decreased.

Compared to aluminum, copper has a relatively lower electrical resistivity and better electron-migration resistance. Hence, copper has been widely used as an interconnection material to reduce the RC delay. However, copper has a fast diffusion rate at elevated temperatures and is prone to form copper silicide when it is adjacent to silicon or silicon oxide. Thus, copper silicide is usually formed at the interface between the silicon-containing features (i.e., substrate or dielectric layer) and copper which results in increased consumption of Cu, increased RC delay time and p-n junction failure. Thus the overall performance of the semiconductor device is reduced.

Accordingly, a diffusion barrier layer interposed between the silicon-containing members and copper to block copper diffusion and avoid the formation of copper silicide is needed. A good diffusion barrier must meet the following requirements: (1) good ability to block diffusion; (2) good adhesion; and (3) good stability at high temperature. According to the prediction of International Roadmap for Semiconductors (ITRS) 2007 Edition, the thickness of the diffusion barrier layer for copper interconnection will be reduced to 1.1 nm (14 nm node, 2020) from 3.7 nm (50 nm node).

At present, tantalum/tantalum nitride (Ta/TaN) is the most commonly used diffusion barrier, but it may form crystalline tantalum silicide with silicon at a relatively low temperature (i.e., lower than 500° C.). Its application is thus restricted. Ternary alloy, such as TaSiN, TaGeN, TiAlN or WGeN, has been proposed to serve as the diffusion barrier layer to reduce the thickness to below 10 nm. However, it is hard to control the nitrogen content in the ternary alloy during the depositing process. Ru/C is also a material which is also known to serve as a diffusion barrier layer and it may have a thickness of only about 5 nm and may also block the diffusion of copper for about 30 mins at temperatures below 700° C. (Journal of the Electrochemical Society, 2009, vol. 156, no. 9 [Note(s): H724-H728]). However, the thickness of the Ru/C diffusion barrier layer still can't reach the requirements necessary for future semiconductor processing.

Therefore, to address the above issues, it is necessary to develop a novel material which can serve as an ultra thin diffusion barrier with good thermal stability.

### BRIEF SUMMARY OF THE INVENTION

In accordance with one aspect of the present invention, a semiconductor device includes a silicon-containing material; a conductive layer deposited on the silicon-containing material; and a diffusion barrier interposed between the silicon-containing material and the conductive layer, wherein the diffusion barrier is formed of a rare earth scandate.

In accordance with another aspect of the present invention, a damascene structure includes a substrate; a silicon-containing dielectric layer deposited on the substrate; an opening within the silicon-containing dielectric layer; a diffusion barrier lining the opening, wherein the diffusion barrier is formed of a rare earth scandate; and a copper member filling the opening.

A detailed description is given in the following embodiments with reference to the accompanying drawings.

### BRIEF DESCRIPTION OF THE DRAWINGS

The present invention can be further understood by reading the subsequent detailed description and examples with references made to the accompanying drawings, wherein:

FIG. 1 shows a cross-sectional view of a semiconductor device according to an embodiment of the present invention.

FIG. 2 shows a cross-sectional view of a damascene structure according to another embodiment of the present invention.

FIG. 3 shows the electrical resistivities of a semiconductor device after annealing at various temperatures according to an embodiment of the present invention.

FIG. 4 shows the electrical resistivities of a semiconductor device after annealing at 400° C. for various lengths of time according to an embodiment of the present invention.

FIGS. 5A and 5B both show transmission electron microscopy (TEM) micrographs of a semiconductor device after annealing at 600° C. for 1 hour according to an embodiment of the present invention.

### DETAILED DESCRIPTION OF THE INVENTION

The following description is of the best-contemplated mode of carrying out the invention. It is understood that the following disclosure provides many different embodiments, or examples, for implementing different features of the invention. Specific examples of components and arrangements are described below to simplify the present disclosure. These are, of course, merely examples and are not intended to be limiting. For example, the formation of a first feature over, above, below, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. The scope of the invention is best determined by reference to the appended claims.

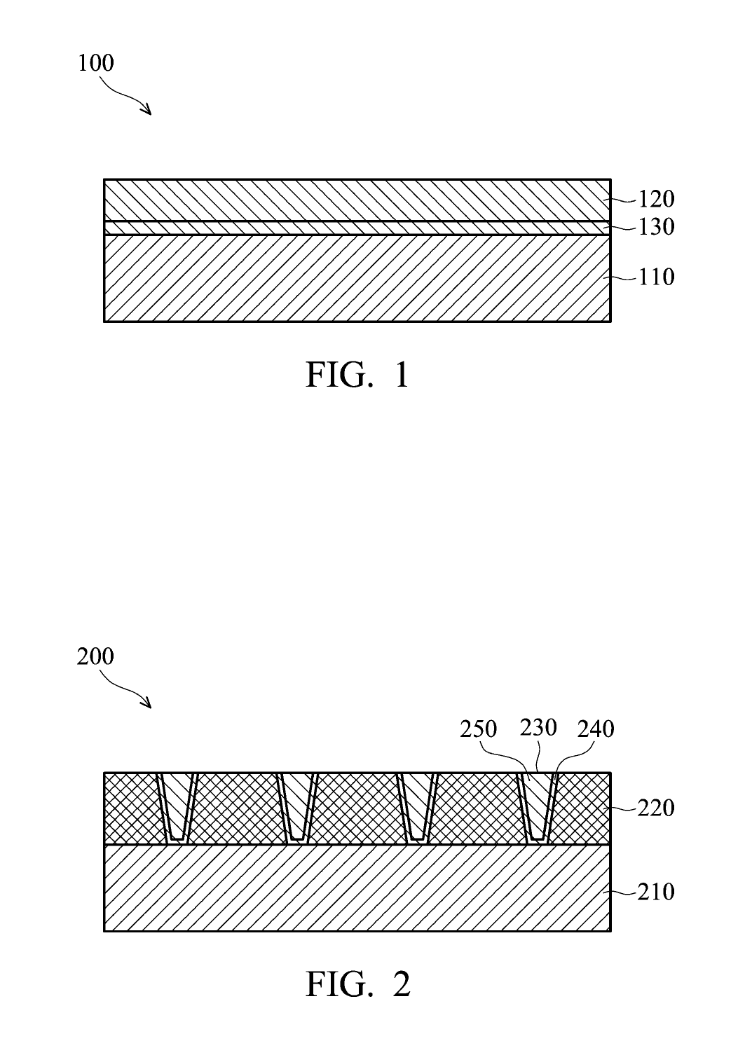

According to one embodiment of the present invention, referring to FIG. 1, which shows a cross-sectional view of a semiconductor device 100. The semiconductor device 100 may comprise a silicon-containing material 110, a conductive layer 120 and a diffusion barrier layer 130. In one embodiment, the silicon-containing material 110 may include, but is not limited to, silicon, silicon oxide (SiOₓ), fluorinated silica glass (FSG) or organosilicate glass (OSG). The silicon-containing material 110 may be formed by spin coating, chemical vapor deposition, epitaxy growth or other suitable deposition techniques. In an exemplary embodiment, the silicon-containing material 110 may be a silicon substrate (i.e., silicon wafer) of a semiconductor device. Alternatively, the silicon-containing material 110 may be a silicon dielectric layer or a gate electrode on a semiconductor substrate. The conductive layer 120 may be formed from a commonly used conductive material such as copper, aluminum, silver, titanium, ruthenium, tantalum nitride, tungsten nitride, alloys thereof or combinations thereof. The conductive layer 120 may be also formed by the commonly used methods such as electroplating, metal organic chemical vapor deposition (MOCVD), chemical vapor deposition, physical vapor deposition, atomic layer deposition or the likes.

The diffusion barrier layer 130 may be formed of a rare earth scandate. Herein, the chemical formula of the rare earth scandate may be presented as RScOₓ, wherein R represents the rare earth element and x is any real number between 3 and 4. The rare earth element may comprise cesium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tu), ytterbium (Yt), lutetium (Lu), scandium (Sc), yttrium (Y) or combinations thereof. In one preferred embodiment, the diffusion barrier layer 130 may comprise holmium scandate (HoScO₃).

The diffusion barrier layer 130 may be formed by magnetron sputtering, chemical vapor deposition, physical vapor deposition, atomic layer deposition, electroplating, or other suitable deposition techniques. Furthermore, the diffusion barrier layer 130 disclosed herein is an ultra thin layer, which may have a thickness of between about 2 and 50 nm. For example, in one embodiment, the thickness of the diffusion barrier layer 130 may be less than 5 nm, preferably less than 3 nm.

Also, the diffusion barrier layer 130 has good thermal stability. It is already known that the diffusion blocking ability of an amorphous rare earth scandate is usually better than a crystalline one. In one embodiment, the diffusion barrier layer 130 is amorphous. Furthermore, the diffusion barrier layer 130 is still amorphous at a temperature of at least 600° C. for at least 1 hour. In other words, the diffusion barrier layer 130 can effectively block the conductive layer 130 from diffusing to the silicon-containing material 110 at a temperature of at least 600° C. for at least 1 hour. In another embodiment, the diffusion barrier layer 130 can effectively block the diffusion from the conductive layer 130 to the silicon-containing material 110 at a temperature of at least 400° C. for at least 50 hours.

According to another embodiment of the present invention, referring to FIG. 2, which shows a cross-sectional view of a damascene structure 200. It should be noted that although FIG. 2 merely illustrates a single damascene structure 200, a dual damascene structure is also applicable. The damascene structure 200 may comprise a substrate 210 and a dielectric layer 220 formed thereon. The substrate 210 and the dielectric layer 220 may comprise, but are not limited to, a silicon-containing material such as silicon, silicon oxide (SiOₓ), fluorinated silica glass (FSG) or organosilicate glass (OSG), which may be formed by spin coating, chemical vapor depositing, epitaxy growth or other suitable deposition techniques. In one embodiment, the dielectric layer 220 is deposited on the substrate 210, such as a silicon oxide dielectric layer deposited on a silicon wafer. An opening 230 within the dielectric layer 220 is lined by a diffusion barrier layer 240, and the remaining portion of the opening 230 is filled by a copper member 250.

The opening 230 may be formed by photolithography and etching processes. The typical photolithography process may comprise multiple steps, such as resist coating, soft baking, mask alignment, development and hard baking. A patterned photoresistant layer is thus formed by the photolithography process and then etched by an anisotropic dry etching process, such as reactive ion etching (RIE) or plasma etching, to form the opening 230. In one embodiment, the opening 230 is a via opening, and the copper member 250 within the via opening is a copper plug. In another embodiment, the opening 230 is an interconnect trench, and the copper member 250 within interconnect trench is a copper interconnection.

The diffusion barrier layer 240 may be formed of a rare earth scandate. Hence, the formation of copper silicide is inhibited since the diffusion from the copper member 250 is blocked by the diffusion barrier layer 240. The diffusion barrier layer 240 may be formed by magnetron sputtering, chemical vapor deposition, physical deposition, atom layer deposition, electroplating or other suitable deposition techniques. The diffusion barrier layer 240 may have a thickness of between about 2 and 50 nm, preferably, less than 5 nm, and ideally, less than 3 nm. Preferably, the diffusion barrier layer 240 is amorphous. In one embodiment, the diffusion barrier layer 240 is still amorphous at a temperature of at least 600° C. for duration of at least 1 hour. In other words, the diffusion barrier layer 240 can effectively block the copper member 250 from diffusing to the dielectric layer 220 at a temperature of at least 600° C. for at least 1 hour. In another embodiment, the diffusion barrier layer 240 can effectively block the diffusion from the copper member 250 to the dielectric layer 220 at a temperature of at least 400° C. for at least 50 hours.

In summary, the present invention herein provides a semiconductor device and a damascene structure, each comprising a diffusion barrier layer formed of a rare earth scandate. The diffusion barrier layer has an ultra thin thickness with good thermal stability. For example, the diffusion barrier layer is still amorphous at high temperature (i.e., 600° C.) with a thickness of less than 3 nm. Thus, the diffusion barrier layer can effectively block diffusion from the conductive material to the silica-containing material and increased electrical resistivity resulting from the formation of copper silicide may be avoided. Furthermore, the diffusion barrier layer may be formed by commonly used deposition methods and the composition of the diffusion barrier layer is easy to control. Hence, a semiconductor device and a damascene structure featuring a novel ultra thin diffusion barrier layer are provided. The ultra thin diffusion barrier is suitable for use in future semiconductor processing and manufacturing.

### Example 1

Holmium oxide (Ho₂O₃) and scandium oxide (Sc₂O₃) powders were mixed, milled, and then calcined at 1100° C. for 4 hours. The fine powder was mixed with polyethylene (binder), burned at 550° C. for 10 hours and sintered at 1300° C. for 2 hours to form a holmium scandate (HoScO₃) sputtering target. A holmium scandate layer with thickness of 3 nm was deposited onto a silicon wafer by using the target with radio frequency magnetron sputtering process at a base pressure of <8×10⁻⁷ torr and a working pressure of 5×10⁻³ torr (Ar/O₂). A copper layer was then deposited onto the holmium scandate layer by electroplating under the same vacuum. The elemental composition of the holmium scandate layer was confirmed by electron probe microanalysis, to be Ho: 18.5%, Sc: 16.4% and O: 65.1%. The microstructure of the holmium scandate layer was analyzed by transmission electron spectroscopy (TEM). The electrical resistivity of copper film was measured by using a four-point probe method.

### Example 2

The same procedure as in Example 1 was repeated, except that a holmium scandate layer with a thickness of 5 nm was deposited onto a silicon wafer.

### Example 3

The same procedure as in Example 1 was repeated, except that a holmium scandate layer with a thickness of 10 nm was deposited onto a silicon wafer

### Comparative Example

The same procedure as in Example 1 was repeated, except that no holmium scandate layer was deposited onto the silicon wafer.

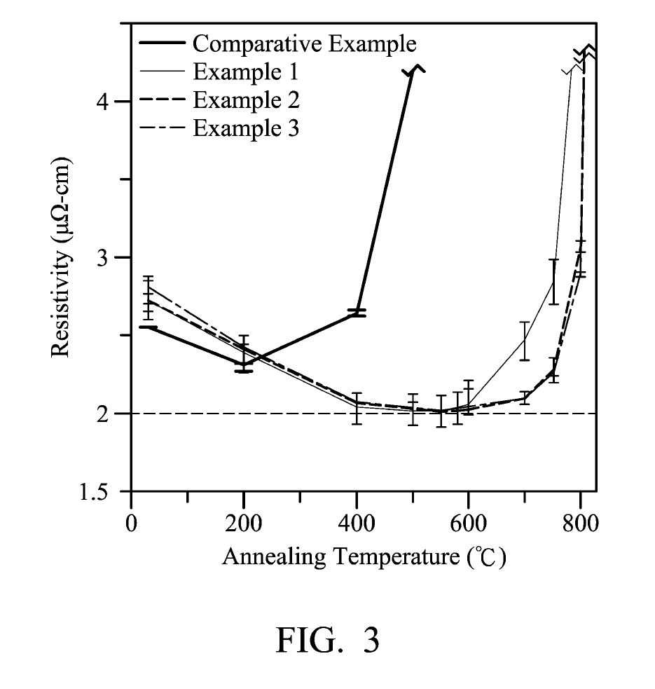

FIG. 3 shows the electrical resistivities of the samples of Examples 1-3 and Comparative Example after annealing for 1 hour at various temperatures. As shown in FIG. 3, the electrical resistivities of all samples of Examples 1-3 and Comparative Example were slightly reduced after annealing at 400° C. for 1 hour. This is attributed to the grain growth in copper and no significant Cu/Si interactions during the annealing process at this temperature. However, for the barrier-less sample (Comparative Example), the resistivity shows a dramatic increase at a temperature above 400° C. due to the catastrophic interaction diffusion between Cu and Si. For Example 1, the resistivity reached to the lowest value of about 2.0 μΩ-cm at about 600° C., indicating that the 3 nm HoScO₃ diffusion barrier layer played an important role to block the diffusion between Cu and Si at 600° C. With the thickness of the diffusion barrier layer increased to 5 nm and 10 nm (Examples 2 and 3), the blocking performance of the barrier was also improved. Only a slight increase of the resistivity was observed when the annealing temperature was increased to 750° C. Accordingly, the stability of the resistivity is governed by the thickness of the diffusion barrier layer when the annealing temperature is above 600° C.

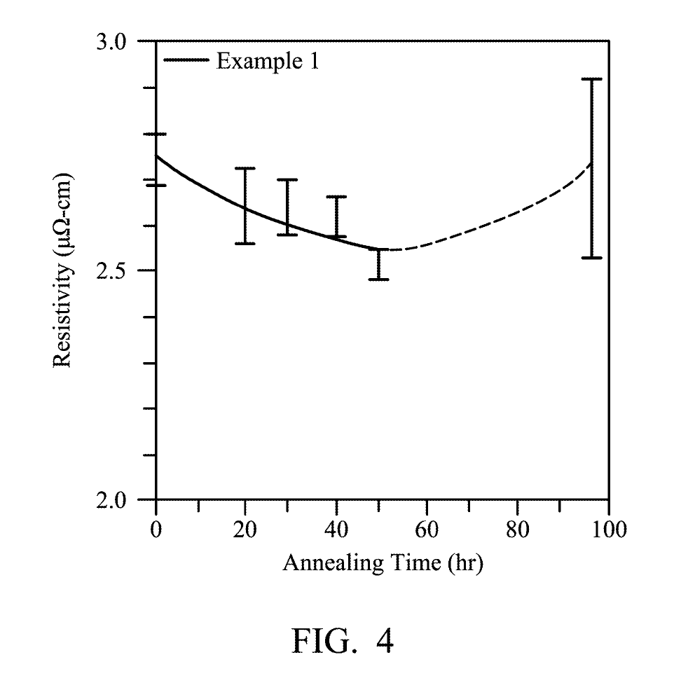

FIG. 4 shows the resistivity of the sample of Example 1 after annealing at 400° C. for various time periods. As shown in FIG. 4, the resistivity decreased with annealing time and reached the lowest value in the range of 2.5-2.7 μΩ-cm for the duration of 50 hours or less. The resistivity began to slowly increase after 50 hours. Thus, the 3 nm HoScO₃ barrier layer can block the diffusion between Cu and Si at 400° C. for at least 50 hours.

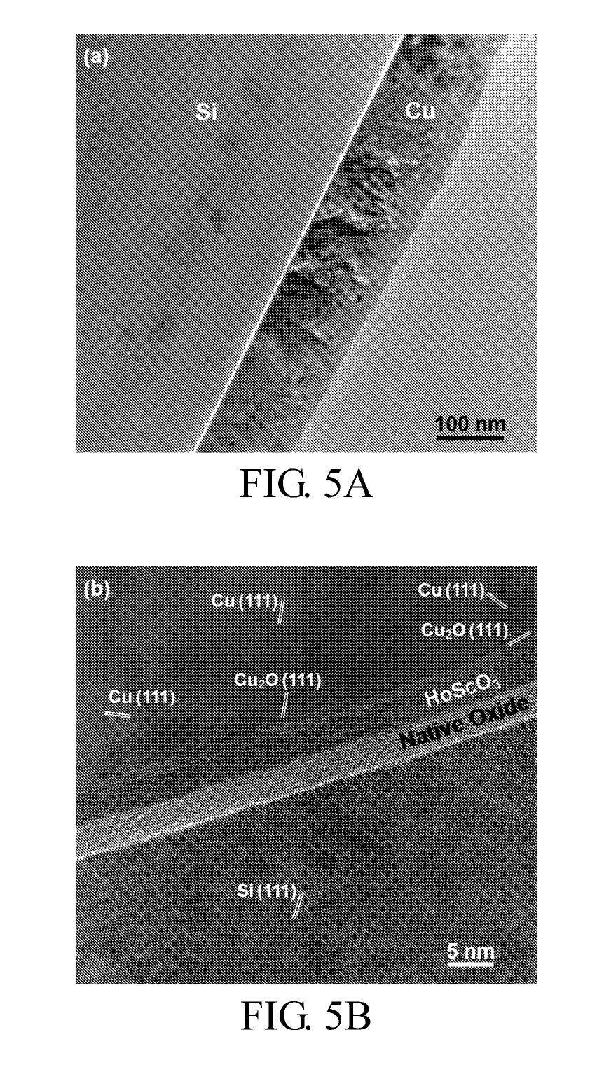

FIGS. 5A and 5B show the transmission electron spectroscopy (TEM) micrographs of Example 1 after annealing at 600° C. for 1 hour. FIG. 5A shows a low resolution TEM micrograph (200 nm scale) and FIG. 5B shows a high resolution TEM micrograph (50 nm scale). Both FIGS. 5A and 5B show that there was no copper silicide formed at the interface between Cu and silicon wafers after annealing at 600° C. for 1 hour. Furthermore, the HoScO₃ diffusion barrier layer still maintained an amorphous state. It is because the rare earth scandate would not transform from an amorphous state to crystalline state until a temperature above 1000° C. was reached. Furthermore, it is observed that native oxide was formed on the silicon wafer at high temperature, but the HoScO₃ diffusion barrier layer can still effectively block the diffusion between Cu and Si.

While the invention has been described by way of example and in terms of the preferred embodiments, it is to be understood that the invention is not limited to the disclosed embodiments. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor device, comprising:
a silicon-containing material;
a conductive layer deposited on the silicon-containing material; and
a diffusion barrier interposed between the silicon-containing material and the conductive layer, wherein the diffusion barrier is formed of a rare earth scandate.

2. The semiconductor device as claimed in claim 1, wherein the silicon-containing material is a substrate, a dielectric layer or a gate electrode.

3. The semiconductor device as claimed in claim 1, wherein the silicon-containing material comprises silicon, silicon oxide or combinations thereof.

4. The semiconductor device as claimed in claim 1, wherein the conductive layer comprises copper, aluminum, gold, silver, titanium, ruthenium, titanium nitride, tungsten nitride alloys thereof or combinations thereof.

5. The semiconductor device as claimed in claim 1, wherein the rare earth scandate comprises cesium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tu), ytterbium (Yt), lutetium (Lu), scandium (Sc), yttrium (Y) or combinations thereof.

6. The semiconductor device as claimed in claim 1, wherein the rare scandate is holmium scandate.

7. The semiconductor device as claimed in claim 1, wherein the rare earth scandate is amorphous.

8. The semiconductor device as claimed in claim 1, wherein the thickness of the diffusion barrier is less than about 3 nm.

9. The semiconductor device as claimed in claim 1, wherein the thickness of the diffusion barrier is between about 2 and 50 nm.

10. The semiconductor device as claimed in claim 1, wherein the diffusion barrier is capable of blocking the diffusion between silicon and the conductive layer at a temperature of at least 400° C. for at least 50 hours.

11. The semiconductor device as claimed in claim 1, wherein the diffusion barrier is capable of blocking the diffusion between silicon and the conductive layer at a temperature of at least 600° C. for at least 1 hour.

12. A damascene structure, comprising:
a substrate;
a silicon-containing dielectric layer deposited on the substrate;
an opening within the silicon-containing dielectric layer;
a diffusion barrier lining the opening, wherein the diffusion barrier is formed of a rare earth scandate; and
a copper member filling the opening.

13. The damascene structure as claimed in claim 12, wherein the rare earth scandate comprises cesium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tu), ytterbium (Yt), lutetium (Lu), scandium (Sc), yttrium (Y) or combinations thereof.

14. The damascene structure as claimed in claim 12, wherein the rare scandate is holmium scandate.

15. The damascene structure as claimed in claim 12, wherein the thickness of the diffusion barrier is less than about 3 nm.

16. The damascene structure as claimed in claim 12, wherein the rare earth scandate is amorphous.

17. The damascene structure as claimed in claim 12, wherein the diffusion barrier is capable of blocking the diffusion between silicon and the copper conductive element at a temperature of at least 400° C. for at least 50 hours.

18. The damascene structure as claimed in claim 12, wherein the diffusion barrier is capable of blocking the diffusion between silicon and the copper conductive element at a temperature of at least 600° C. for at least 1 hour.

19. The damascene structure as claimed in claim 12, wherein the opening comprises a via opening, and the copper member is a copper plug.

20. The damascene structure as claimed in claim 12, wherein the opening comprises an interconnection trench, and the copper member is a copper interconnection.
